(19) United States
(12) Patent Application Publication
(10) Pub. No.: US 2026/0090224 A1
(43) Pub. Date: Mar. 26, 2026

(54) DISPLAY PANEL AND DISPLAY APPARATUS

(71) Applicant: KunShan Go-Visionox Opto-Electronics Co., Ltd., Kunshan (CN)

(72) Inventors: Junhui LOU, Kunshan (CN); Rubo XING, Kunshan (CN)

(73) Assignee: KunShan Go-Visionox Opto-Electronics Co., Ltd., Kunshan (CN)

(21) Appl. No.: 19/403,186

(22) Filed: Nov. 27, 2025

Related U.S. Application Data
(63) Continuation of application No. PCT/CN2023/137393, filed on Dec. 8, 2023.

(30) Foreign Application Priority Data
Jun. 27, 2023 (CN) 202310766087.2

(51) Int. Cl. H10K 59/131; H10K 59/122

(52) U.S. Cl. CPC H10K 59/131; H10K 59/122

(57) ABSTRACT

Provided in the present application are a display panel and a display apparatus. The display panel includes a substrate, a first potential portion, an isolation structure, a light-emitting functional layer and a first conductive portion. The first potential portion is arranged on a side of the substrate, the isolation structure is arranged on a side of the first potential portion that faces away from the substrate, the isolation structure is provided with a first through hole extending through the isolation structure in a thickness direction of the substrate, and the first potential portion is at least partially exposed in the first through hole. The light-emitting functional layer is arranged on the side of the first potential portion that faces away from the substrate, the light-emitting functional layer includes a plurality of light-emitting structures, and adjacent light-emitting structures are isolated from each other by means of the isolation structure.

### CROSS-REFERENCE TO RELATED APPLICATIONS

The present application is a continuation of International Application No. PCT/CN2023/137393 filed on December 08, 2023, which claims priority to Chinese Patent Application No. 2023107660872, entitled "DISPLAY PANEL AND DISPLAY APPARATUS" and filed on June 27, 2023, which is incorporated herein by reference in its entirety.

### FIELD

The present application relates to the field of display devices, and particularly to a display panel and a display apparatus.

### BACKGROUND

Flat display panels such as organic light emitting display (OLED) display panels and display panels using light emitting diode (LED) devices have been widely applied to various consumer electronic products such as mobile phones, televisions, personal digital assistants, digital cameras, notebook computers and desktop computers and predominate in display apparatuses thanks to their advantages such as high image quality, energy efficiency, slim design and a wide range of applications.

### SUMMARY

Embodiments of the present application provide a display panel and a display apparatus, which can improve the reliability of electrical connection between internal structures of the display panel.

In a first aspect, the embodiments of the present application provide a display panel. The display panel includes a substrate, a first potential portion, an isolation structure, a light-emitting functional layer and a first conductive portion. The first potential portion is arranged on a side of the substrate, the isolation structure is arranged on a side of the first potential portion that faces away from the substrate, the isolation structure is provided with a first through hole extending through the isolation structure in a thickness direction of the substrate, and the first potential portion is at least partially exposed in the first through hole.

The light-emitting functional layer is arranged on the side of the first potential portion that faces away from the substrate, the light-emitting functional layer includes a plurality of light-emitting structures, and adjacent light-emitting structures are isolated from each other by means of the isolation structure. The first conductive portion is located on a side of the isolation structure that faces away from the substrate, and the first conductive portion is at least partially located in the first through hole and is electrically connected to the first potential portion.

In a second aspect, the embodiments of the present application provide a display apparatus, including a display panel in any one of the above implementations.

The embodiments of the present application provide a display panel and a display apparatus. By adding the first through hole in the isolation structure, the first conductive portion can extend into the first through hole, thereby realizing the electrical connection between the first conductive portion and the first potential portion. In this way, the first conductive portion does not need to extend via an outer sidewall of the isolation structure, which can reduce the risk of the first conductive portion breaking due to the shape of the outer sidewall of the isolation structure and improve the reliability of the electrical connection of the first conductive portion.

### BRIEF DESCRIPTION OF THE DRAWINGS

In order to describe the embodiments of the present application more clearly, the accompanying drawings required for illustration of the embodiments of the present application will be briefly described below. The accompanying drawings described below show merely some of the embodiments of the present application.

FIG. 1 is a schematic structural diagram of a display panel according to an embodiment of the present application;

FIG. 2 is an enlarged schematic structural diagram of region Q in FIG. 1;

FIG. 3 is a schematic cross-sectional structural diagram taken along line A-A in FIG. 2;

FIG. 4 is a schematic cross-sectional structural diagram taken along line B-B in FIG. 2;

FIG. 5 is an enlarged schematic structural diagram of region Q of another display panel according to an embodiment of the present application;

FIG. 6 is a schematic cross-sectional structural diagram taken along line B-B of another display panel according to an embodiment of the present application;

FIG. 7 is an enlarged schematic structural diagram of region Q of yet another display panel according to an embodiment of the present application;

FIG. 8 is a schematic cross-sectional structural diagram taken along line C-C in FIG. 7;

FIG. 9 is an enlarged schematic structural diagram of region Q of still another display panel according to an embodiment of the present application;

FIG. 10 is a schematic cross-sectional structural diagram taken along line D-D in FIG. 9;

FIG. 11 is a schematic cross-sectional structural diagram taken along line A-A of a further display panel according to an embodiment of the present application; and

FIG. 12 is a schematic structural diagram of a display apparatus according to an embodiment of the present application.

### DETAILED DESCRIPTION OF THE EMBODIMENTS

In some display panels, an isolation structure is provided to separate part of film layer structures inside a display panel, to meet the preparation and operational requirements of the display panel. On this basis, a conductor structure may be arranged above the isolation structure for transmitting specific electrical signals. However, due to the structural limitations of the isolation structure itself, it is difficult for the conductor structure above the isolation structure to extend along an outer contour of the isolation structure to a corresponding potential position. Therefore, how to realize potential transmission for the conductive structure above the isolation structure has become an urgent problem to be solved.

In view of the above problems, in a first aspect, referring to FIGS. 1 to 4, the embodiments of the present application provide a display panel. The display panel includes a substrate 10, a first potential portion D1, an isolation structure 30, a light-emitting functional layer 20 and a first conductive portion 41. The first potential portion D1 is arranged on a side of the substrate 10, the isolation structure 30 is arranged on a side of the first potential portion D1 that faces away from the substrate 10, the isolation structure 30 is provided with a first through hole H1 extending through the isolation structure in a thickness direction X of the substrate 10, and the first potential portion D1 is at least partially exposed in the first through hole H1.

The light-emitting functional layer 20 is arranged on the side of the first potential portion D1 that faces away from the substrate 10, the light-emitting functional layer 20 includes a plurality of light-emitting structures 21, and adjacent light-emitting structures 21 are isolated from each other by means of the isolation structure 30. The first conductive portion 41 is located on a side of the isolation structure 30 that faces away from the substrate 10, and the first conductive portion 41 is at least partially located in the first through hole H1 and is electrically connected to the first potential portion D1.

The substrate 10 mainly functions as a support and carrier, and the other film layers are sequentially stacked on the substrate 10. The "stacked" mentioned here means that the other film layers are sequentially arranged in the thickness direction X of the substrate 10. The substrate 10 may comprise a plurality of film layer structures, and the specific composition of the film layer structures of the substrate 10 is not limited in the embodiments of the present application. Moreover, thickness directions X of the other film layers located on a side of the substrate 10 is generally consistent with the thickness direction X of the substrate 10 itself. Therefore, for ease of illustration, the thickness direction X of the substrate 10 or the thickness directions X of the other film layers mentioned later in the embodiments of the present application are all indicated by the same direction.

The light-emitting functional layer 20 is located on a side of the substrate 10 and includes a plurality of light-emitting structures 21, and the light-emitting structures 21 are the main devices for achieving light-emitting display. The light-emitting structures 21 include, but are not limited to, red light-emitting structures 21 for emitting red light, green light-emitting structures 21 for emitting green light, and blue light-emitting structures 21 for emitting blue light. Each light-emitting structure 21 may include a hole inject layer (HIL), a hole transport layer (HTL), a light-emitting layer, an electron inject layer (EIL), and an electron transport layer (ETL) that are stacked.

In one embodiment, the display panel further includes a first electrode 42 and a second electrode 43 located on two sides of the light-emitting structure 21 in the thickness direction X. The first electrode 42 is located on a side of the light-emitting structure 21 that faces away from the substrate 10, and the second electrode 43 is located on a side of the light-emitting structure 21 that faces the substrate 10. The first electrode 42 and the second electrode 43 jointly drive and control whether the light-emitting structure 21 emits light. As an example, the first electrode 42 is a cathode, and the second electrode 43 is an anode.

The isolation structure 30 and the light-emitting functional layer 20 are located on the same side of the substrate 10. One or more isolation structures 30 may be provided. The isolation structure 30 can function to separate part of the film layers. As an example, a plurality of isolation structures 30 are provided, and the plurality of isolation structures 30 are spaced apart from each other. The plurality of isolation structures 30 can separate the light-emitting functional layer 20 during the preparation of the light-emitting functional layer 20, and orthographic projections of the light-emitting structures 21 in the light-emitting functional layer 20 on the substrate 10 and orthographic projections of the isolation structures 30 on the substrate 10 are distributed in a staggered manner.

In particular, due to the limitations of the shape and structure of the isolation structure 30, it is difficult for film layer materials to extend along a sidewall contour of the isolation structure 30 during the preparation of part of the film layer structures, causing part of film layers to break at the position of the isolation structure 30, and thus achieving the separation effect of the isolation structure 30. The specific shape and size of the isolation structure 30 are not limited in the embodiments of the present application, as long as the isolation structure 30 can perform the separation function. As an example, a longitudinal section of the isolation structure 30 may be in an inverted trapezoid structure.

In addition to the light-emitting functional layer 20 and the isolation structure 30, the display panel is provided with the first potential portion D1 and the first conductive portion 41. Both the first potential portion D1 and the first conductive portion 41 include conductive materials. The first potential portion D1 is used for transmitting a specific potential signal, and to meet the needs of signal transmission, and the first conductive portion 41 needs to be electrically connected to the first potential portion D1. The function of the first conductive portion 41 is not limited in the embodiments of the present application.

The first potential portion D1 is located on a side of the isolation structure 30 that faces the substrate 10, and the first conductive portion 41 is located on a side of the isolation structure 30 that faces away from the substrate 10. As can be seen from the foregoing, due to the limitations of the structural shape of the isolation structure 30 itself, it is difficult for the first conductive portion 41 to extend along a sidewall of the isolation structure 30 to the first potential portion D1. On that basis, the first through hole H1 is additionally added in the isolation structure 30 in the embodiments of the present application, and the electrical connection between the first conductive portion 41 and the first potential portion D1 is realized by means of the first through hole H1.

In particular, the first through hole H1 is located inside the isolation structure 30, and the first potential portion D1 is at least partially exposed in the first through hole H1. The first conductive portion 41 can be electrically connected to the first potential portion D1 as long as the first conductive portion 41 can at least partially extend into the first through hole H1. Further, the size of the first through hole H1 can be appropriately reduced to make it easier for the first conductive portion 41 to fill into the first through hole H1, thereby realizing the electrical connection between the first conductive portion 41 and the first potential portion D1. In one embodiment, when forming the first through hole H1, the shape of a sidewall around the first through hole H1 can be adjusted, and the first conductive portion 41 can extend to the first potential portion D1 by means of the sidewall of the first through hole H1, thereby realizing the electrical connection between the first conductive portion 41 and the first potential portion D1.

In summary, in the embodiments of the present application, by adding the first through hole H1 in the isolation structure 30, the first conductive portion 41 can extend into the first through hole H1, thereby realizing the electrical connection between the first conductive portion 41 and the first potential portion D1. In this way, the first conductive portion 41 does not need to extend via an outer sidewall of the isolation structure 30, which can reduce the risk of the first conductive portion 41 breaking due to the shape of the outer sidewall of the isolation structure 30 and improve the reliability of the electrical connection of the first conductive portion 41.

In some embodiments, as shown in FIGS. 1 to 4, the display panel further includes a first electrode 42 arranged on the side of the light-emitting functional layer 20 that faces away from the substrate 10. An orthographic projection of the first electrode 42 on the substrate 10 overlaps with the orthographic projection of the light-emitting structure 21 on the substrate 10. The first electrode 42 and the first conductive portion 41 are insulated from each other by means of the isolation structure 30.

The first electrode 42 is located on the side of the light-emitting structure 21 that faces away from the substrate 10. The isolation structure 30 has a second surface M2 that faces away from the substrate 10. The first electrode 42 is located on a side of the second surface M2 that faces the substrate 10, and the first conductive portion 41 is located on a side of the second surface M2 that faces away from the substrate 10. The first electrode 42 may abut against the sidewall of the isolation structure 30, or the first electrode 42 may be spaced apart from the isolation structure 30, which is not limited in the embodiments of the present application.

Both the first electrode 42 and the first conductive portion 41 include the conductive materials, and signal transmission between the first electrode 42 and the first conductive portion 41 needs to be realized by means of the isolation structure 30. On this basis, the mutual insulation between the first electrode 42 and the first conductive portion 41 can be realized by controlling part or all of the isolation structure 30 to include an insulating material.

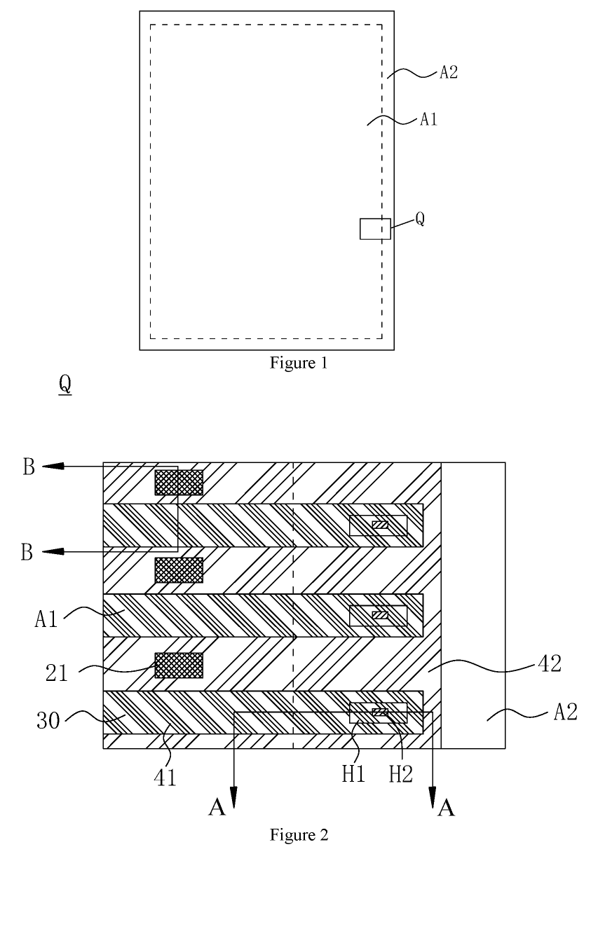

It should be noted that the number of first electrodes 42 is not limited in the embodiments of the present application. As an example, as shown in FIG. 2, only one first electrode 42 may be provided. The orthographic projection of the first electrode 42 on the substrate 10 covers the orthographic projections of all the light-emitting structures 21 on the substrate 10. However, due to the presence of the isolation structure 30, the orthographic projection of the first electrode 42 on the substrate 10 is in a mesh shape or other shapes.

In addition, since the first through hole H1 is provided inside the isolation structure 30 and the first electrode 42 is located outside the isolation structure 30, the first electrode 42 will not come into contact with the first conductive portion 41 located in the first through hole H1 and the first potential portion D1 exposed in the first through hole H1. This can reduce the risk of signal crosstalk between them, thereby ensuring the reliability of signal transmission for the first conductive portion 41 and the first electrode 42 respectively.

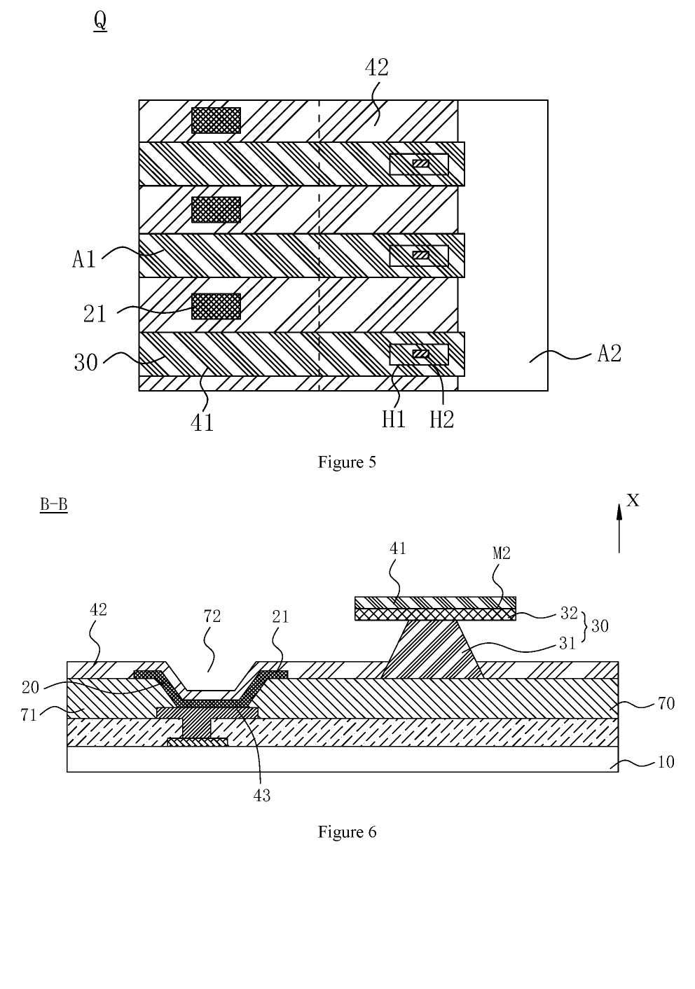

In some other embodiments, referring to FIG. 5, a plurality of first electrodes 42 are provided, and adjacent first electrodes 42 are respectively arranged on different sides of the isolation structure 30.

In the embodiments of the present application, due to the presence of the isolation structure 30, a plurality of first electrodes 42 are provided. The orthographic projection of a first electrode 42 on the substrate 10 may cover one light-emitting structure 21, or in one embodiment, the orthographic projection of a first electrode 42 on the substrate 10 overlaps with the orthographic projections of a plurality of light-emitting structures 21 on the substrate 10. This enables a first electrode 42 to control a plurality of light-emitting structures 21 to achieve light-emitting display simultaneously, thereby realizing zoned control of the display panel.

The number, size, and shape of the first electrode 42 are not limited in the embodiments of the present application. The number, size, and shape of the first electrode 42 may be determined by those of the isolation structure 30. As an example, when the orthographic projection of the isolation structure 30 on the substrate 10 is of a strip-like structure, and a plurality of strip-like structures are arranged side by side, the orthographic projection of the first electrode 42 on the substrate 10 may also be of a strip-like structure, and the first electrode 42 is sandwiched between two adjacent isolation structures 30.

In some embodiments, the first electrode 42 and the first conductive portion 41 include the same material.

In the embodiments of the present application, since the first electrode 42 and the first conductive portion 41 include the same material, the first electrode 42 and the first conductive portion 41 can be formed together in the same preparation process. In particular, after the isolation structure 30 is prepared, a specific conductive material may be evaporated onto the display panel. Part of the material falls on the side of the isolation structure 30 that faces away from the substrate 10, to form the first conductive portion 41, and part of the material falls outside the isolation structure 30, to form the first electrode 42.

This design enables the simultaneous formation of the first electrode 42 and the first conductive portion 41, thereby simplifying the preparation process of the display panel and improving preparation efficiency. In addition, the first conductive portion 41 and the first electrode 42 can be prepared using the same material. That is, the first conductive portion 41 can be prepared without additional materials. This also reduces the preparation cost corresponding to the first conductive portion 41, resulting in high practicality.

The material composition of the first electrode 42 and the first conductive portion 41 is not limited in the embodiments of the present application. As an example, the first electrode 42 and the first conductive portion 41 may include a metal material, including but not limited to silver, titanium, and aluminum.

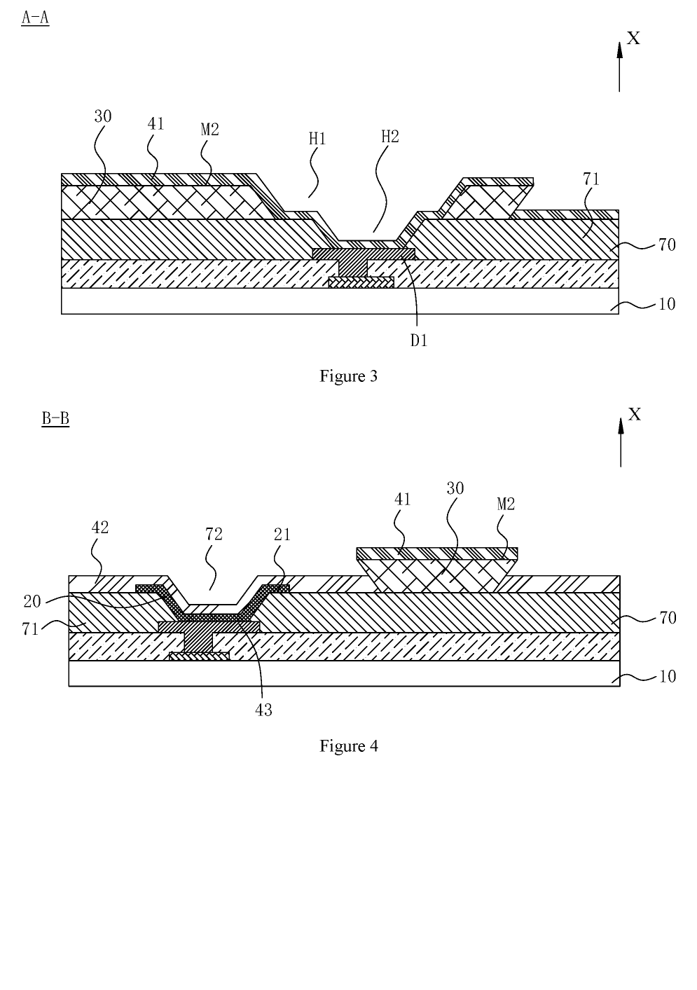

In some embodiments, as shown in FIG. 4, in a direction away from the substrate 10, a cross-sectional dimension of at least part of the isolation structure 30 exhibits a gradually increasing trend.

As can be seen from the foregoing, due to the presence of the isolation structure 30, during the preparation of the first electrode 42, the material falling on the side of the isolation structure 30 that faces away from the substrate 10 will not connect to the first electrode 42, making it possible to form the first conductive portion 41 and the first electrode 42 that are insulated from each other. In view of this, the shape and size of the isolation structure 30 need to be adjusted to ensure that the isolation structure 30 can separate the first conductive portion 41 from the first electrode 42.

Therefore, in the embodiments of the present application, the isolation structure 30 is configured, in the direction away from the substrate 10, the cross-sectional dimension of at least part of the isolation structure 30 exhibits a gradually increasing trend. This helps to increase the difficulty for the film layer structure to extend along the sidewall of the isolation structure 30, thereby reducing the probability of connection between the first conductive portion 41 and the first electrode 42 and improving the insulation reliability between them.

The isolation structure 30 may have various structural forms. As an example, the longitudinal section of the isolation structure 30 may be in an inverted trapezoid structure. That is, in the direction away from the substrate 10, the cross-sectional dimensions of all parts of the isolation structure 30 exhibit a gradually increasing trend. In some embodiments, as shown in FIG. 6, the isolation structure 30 may include a first part 31 and a second part 32 located on a side of the first part 31 that faces away from the substrate 10, and an orthographic projection of the first part 31 on the substrate 10 is located within an orthographic projection of the second part 32 on the substrate 10. In this way, at the junction of the first part 31 and the second part 32, the cross-sectional dimension of the isolation structure 30 changes abruptly, thereby further increasing the probability of the film layer structure breaking at the junction of the first part 31 and the second part 32.

In some embodiments, the first conductive portion 41 is used for transmitting touch signals. That is, the first conductive portion 41 can be multiplexed as a touch electrode to meet the touch requirements of the display panel.

Further, in some embodiments, as shown in FIGS. 1 to 4, the display panel has a first area A1 and a second area A2 arranged around the first area A1. The light-emitting structures 21 are arranged in the first area A1, and the first potential portion D1 is arranged in the second area A2.

The display panel has at least two areas, namely the first area A1 and the second area A2. The first area A1 is an area of the display panel that is used for achieving a display effect, and the light-emitting structures 21 are arranged in the first area A1. The second area A2 is arranged around the first area A1 and can be used for arranging structures such as a driving circuit and a driving chip. The shapes and sizes of the first area A1 and the second area A2 are not limited in the embodiments of the present application. As an example, the first area A1 may have a rectangular structure, and the second area A2 may have a square ring structure. In one embodiment, the first area A1 may have a circular structure, and the second area A2 may have an annular structure.

On this basis, the first potential portion D1 is located in the second area A2. The first potential portion D1 may be directly connected to a driving chip for providing touch signals, or a specific signal trace may be directly connected to the driving chip for providing touch signals, and then the first potential portion D1 is connected to the signal trace through a via connection or other means to realize the transmission of touch signals.

Further, since the first through hole H1 in the isolation structure 30 needs to be arranged corresponding to the first potential portion D1, a second through hole H2 needs to be at least partially located in the second area A2, and the isolation structure 30 needs to extend from the first area A1 into the second area A2. Moreover, since the first conductive portion 41 needs to be connected to the first potential portion D1, the first conductive portion 41 also needs to extend from the first area A1 into the second area A2.

In the embodiments of the present application, by arranging the first potential portion D1 in the second area A2, the first through hole H1 is at least partially located in the second area A2. This helps to reduce the impact of structures such as the first potential portion D1 and the first through hole H1 on the display effect of the first area A1, thereby improving the display uniformity of the display panel.

In some embodiments, the first electrode 42 is partially located in the second area A2.

In the embodiments of the present application, since the first electrode 42 and the first conductive portion 41 can be made of the same material and formed in the same preparation process, and the first conductive portion 41 needs to be at least partially located in the second area A2, the preparation range of the first electrode 42 can be controlled to be partially located in the second area A2 during preparation, allowing the formed first conductive portion 41 to be partially located in the second area A2, and facilitating the electrical connection between the first conductive portion 41 and the first potential portion D1.

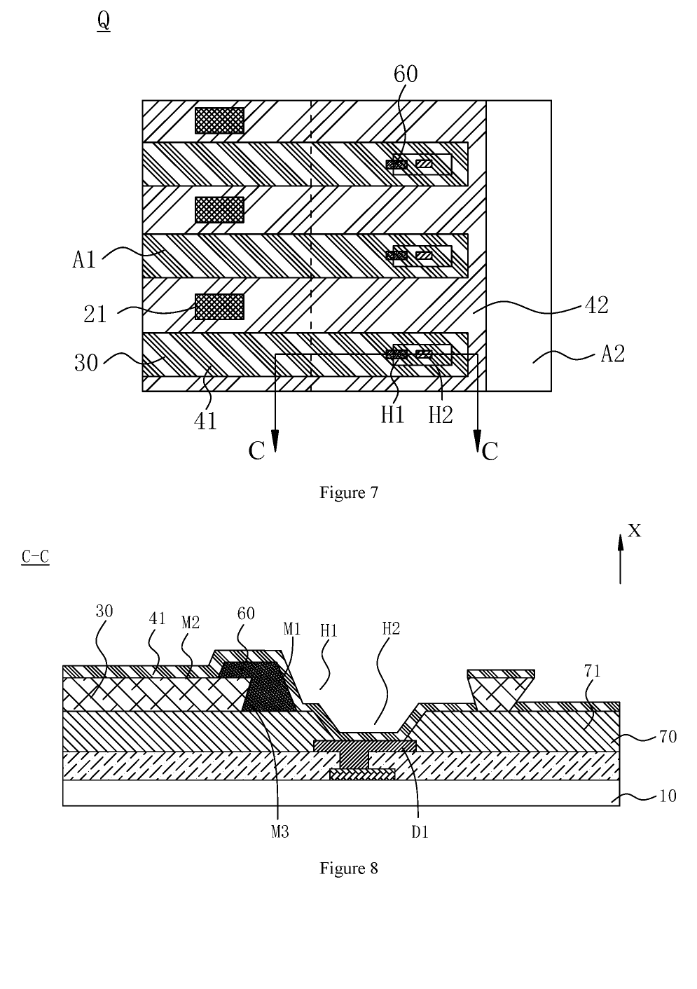

In some embodiments, referring to FIGS. 7 and 8, the display panel further includes a support portion 60 located on a side of the first potential portion D1 and in contact with the isolation structure 30. The support portion 60 is at least partially located in the first through hole H1, and the support portion 60 has a first surface M1 close to the first potential portion D1. In the direction away from the substrate 10, the first surface M1 has a tendency to approach the isolation structure 30. The first electrode 42 extends to the first potential portion D1 via the first surface M1.

As can be seen from the foregoing, in order to realize the electrical connection between the first potential portion D1 and the first conductive portion 41, a first through hole H1 is provided in the isolation structure 30. However, during the preparation of the isolation structure 30, a first sidewall M3 located around the first through hole H1 may be as shown in FIG. 8. In this case, since an angle between the first sidewall M3 and the second surface M2 is an acute angle, it is difficult for the first conductive portion 41 to extend along the first sidewall M3 to the first potential portion D1.

In view of this, in the embodiments of the present application, the support portion 60 is added, and the support portion 60 is located on a side of the first potential portion D1 and is at least partially located in the first through hole H1. In this way, the first conductive portion 41 can extend along the first surface M1 of the support portion 60 to the first potential portion D1. The support portion 60 may be entirely located in the first through hole H1, or only partially located in the first through hole H1, and the support portion 60 may be in contact with the first sidewall M3, or may not be in contact with the first sidewall M3, which are not limited in the embodiments of the present application.

On this basis, in the embodiments of the present application, the first surface M1 is configured, in the direction away from the substrate 10, the first surface M1 has a tendency to approach the isolation structure 30, and an inclination direction of the first surface M1 is different from that of the first sidewall M3, thereby reducing the difficulty for the first conductive portion 41 to extend along the first surface M1 and lowering the risk of the first conductive portion 41 breaking at the first surface M1. This further helps to improve the reliability of the electrical connection between the first conductive portion 41 and the first potential portion D1.

In addition, the specific position of the support portion 60 relative to the first potential portion D1 is not limited in the embodiments of the present application. The support portion 60 may be located on a side of the first potential portion D1 close to the first area A1, or on a side of the first potential portion D1 away from the first area A1, or on different sides of the first potential portion D1 in other directions. In one embodiment, the support portion 60 is located on a side of the first potential portion D1 that faces the first area A1.

In some embodiments, the isolation structure 30 has a first sidewall M3 located on a side of the first through hole H1 close to the first area A1, and the support portion 60 covers at least part of the first sidewall M3.

This design can further reduce the size of the material for forming the first conductive portion 41 that adheres to the first sidewall M3, allowing more material to adhere to the first surface M1 of the support portion 60. This reduces the risk of the first conductive portion 41 breaking at the first sidewall M3 and improves the reliability of the electrical connection between the first conductive portion 41 and the first potential portion D1.

In some embodiments, part of the support portion 60 is located on the side of the isolation structure 30 that faces away from the substrate 10, that is, the dimension of the support portion 60 in the thickness direction X is greater than that of the first sidewall M3 in the thickness direction X. This allows the first conductive portion 41 to more easily extend along the first surface M1 of the support portion 60, thereby reducing the risk of the first conductive portion 41 breaking and ensuring that the first conductive portion 41 and the first potential portion D1 can be electrically connected.

In some embodiments, as shown in FIGS. 3 and 4, the display panel further includes a pixel definition layer 70 arranged on the side of the first potential portion D1 that faces away from the substrate 10. The pixel definition layer 70 includes a pixel defining portion 71 and pixel openings 72 enclosed by the pixel defining portion 71. The light-emitting structures 21 are at least partially located in the pixel openings 72, and the isolation structure 30 is arranged on a side of the pixel defining portion 71 that faces away from the substrate 10.

The pixel defining portion 71 is provided with a second through hole H2 extending through the pixel defining portion in the thickness direction X, the first through hole H1 is in communication with the second through hole H2, and the first potential portion D1 is at least partially exposed in the second through hole H2.

The pixel definition layer 70 includes the pixel defining portion 71, and the pixel defining portion 71 functions as a support for the isolation structure 30. As an example, the orthographic projection of the isolation structure 30 on the substrate 10 is located within an orthographic projection of the pixel defining portion 71 on the substrate 10. The pixel defining portion 71 can enclose the pixel openings 72, and the pixel openings 72 are located in the first area A1. The light-emitting structures 21 are generally arranged corresponding to the pixel openings 72.

The first potential portion D1 is located on a side of the pixel definition layer 70 that faces the substrate 10, and the first potential portion D1 is generally arranged to avoid the pixel openings 72. Therefore, to realize the electrical connection between the first potential portion D1 and the first conductive portion 41, the second through hole H2 is added in the pixel defining portion 71 in the embodiments of the present application. The second through hole H2 may be located in the second area A2 and extends through the pixel defining portion 71 in the thickness direction X, and the first potential portion D1 can be at least partially exposed in the second through hole H2.

Further, in the embodiments of the present application, the first through hole H1 is also arranged corresponding to the second through hole H2, and the first through hole H1 and the second through hole H2 are in communication with each other, thereby ensuring that the first potential portion D1 can be exposed in the first through hole H1. Thus, the first conductive portion 41 can extend into the second through hole H2 through the first through hole H1, and then extend to the first potential portion D1 to realize the electrical connection between the two. A size relationship between the first through hole H1 and the second through hole H2 is not limited in the embodiments of the present application. As an example, an orthographic projection of the second through hole H2 on the substrate 10 is located within an orthographic projection of the first through hole H1 on the substrate 10.

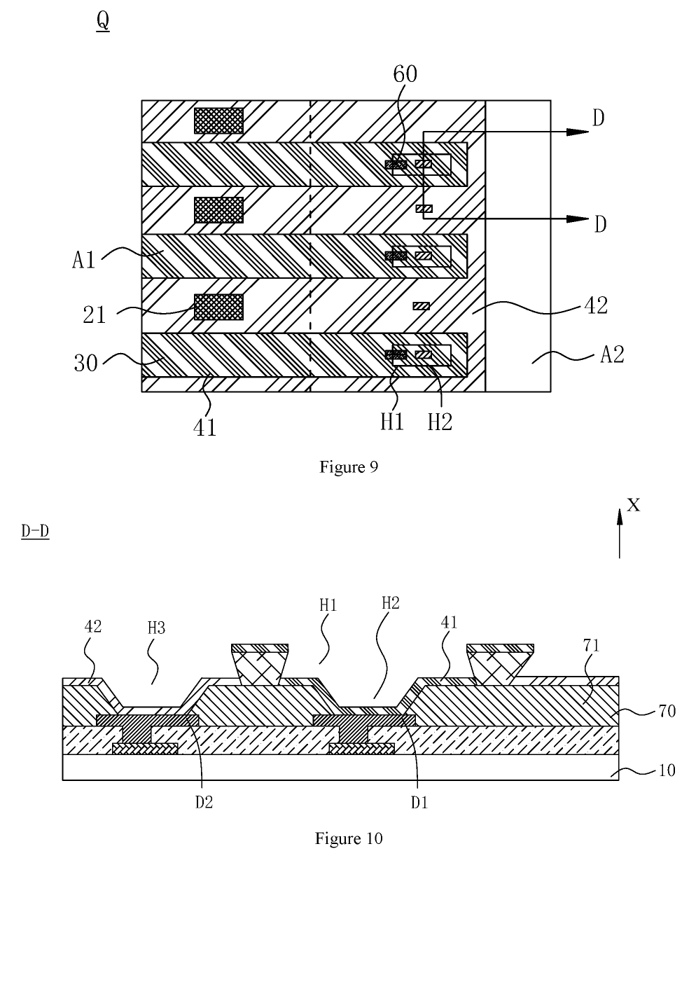

In some embodiments, referring to FIGS. 9 and 10, the display panel further includes a second potential portion D2 arranged on the side of the pixel definition layer 70 that faces the substrate 10. The pixel defining portion 71 is provided with a third through hole H3 extending through the pixel defining portion in the thickness direction X, and the second potential portion D2 is at least partially exposed in the third through hole H3. The first electrode 42 is at least partially located in the third through hole H3 and is electrically connected to the second potential portion D2.

The second potential portion D2 is located on the side of the pixel definition layer 70 that faces the substrate 10, and is used for providing a specific power signal to the first electrode 42. To realize the electrical connection between the first electrode 42 and the second potential portion D2, the third through hole H3 is added in the pixel defining portion 71 in the embodiments of the present application. The second potential portion D2 is exposed in the third through hole H3, and the first electrode 42 can extend into the third through hole H3 and be electrically connected to the second potential portion D2. As an example, the orthographic projection of the first electrode 42 on the substrate 10 covers the orthographic projection of the third through hole H3 on the substrate 10.

In some embodiments, the display panel has a first area A1 and a second area A2 arranged around the first area A1, and the second potential portion D2 is arranged in the second area A2.

In the embodiment of the present application, the second potential portion D2 is arranged in the second area A2. That is, the third through hole H3 is at least partially located in the second area A2. This allows the electrical connection between the first electrode 42 and the second potential portion D2 to be realized in the second area A2, which can reduce the impact of the second potential portion D2 on the display effect and help to improve the display uniformity.

In some embodiments, the first potential portion D1 and the second potential portion D2 are arranged in the same layer.

The first potential portion D1 and the second potential portion D2 are used for transmitting different types of electrical signals, respectively, and both the first potential portion D1 and the second potential portion D2 may be located in the second area A2. Parameters such as the size and number of the first potential portion D1 and the second potential portion D2 are not limited in the embodiments of the present application. As an example, a plurality of first potential portions D1 and a plurality of second potential portions D2 are provided, and the plurality of first potential portions D1 and the plurality of second potential portions D2 may be alternately distributed in the same direction.

Further, in the embodiments of the present application, the first potential portion D1 and the second potential portion D2 are arranged in the same layer, reducing the risk of increasing the overall thickness of the display panel due to the first potential portion D1 and the second potential portion D2 being located in different film layers, helping to reduce the overall thickness of the display panel, and facilitating the realization of a thin and light design.

In some embodiments, the first potential portion D1 and the second potential portion D2 include the same material.

The material composition of the first potential portion D1 and the second potential portion D2 is not limited in the embodiments of the present application. As an example, the first potential portion D1 and the second potential portion D2 may include a metal material, including but not limited to silver, titanium, and aluminum.

In the embodiments of the present application, by configuring the first potential portion D1 and the second potential portion D2 to include the same material and arranging the first potential portion D1 and the second potential portion D2 in the same layer, the first potential portion D1 and the second potential portion D2 can be formed together in the same preparation process, thereby simplifying the preparation process of the display panel and improving the preparation efficiency of the display panel.

In some embodiments, the display panel further includes a second electrode 43 arranged on the side of the light-emitting structure 21 that faces the substrate 10, and the first potential portion D1 and the second electrode 43 are arranged in the same layer.

Both the first electrode 42 and the second electrode 43 are used for driving the light-emitting structures 21 to achieve light-emitting display. A plurality of second electrodes 43 are provided, and the plurality of second electrodes 43 are arranged in one-to-one correspondence with the plurality of light-emitting structures 21. On this basis, in the embodiments of the present application, the first potential portion D1, the second potential portion D2, and the second electrode 43 are all arranged in the same film layer, further reducing the overall thickness of the display panel and realizing a thin and light design of the display panel.

Further, in some embodiments, the first potential portion D1 and the second electrode 43 include the same material, enabling the first potential portion D1 and the second electrode 43 to be formed together in the same preparation process, and thus improving the preparation efficiency of the display panel.

In some embodiments, referring to FIG. 11, the display panel further includes an encapsulation layer 80 arranged on a side of the first electrode 42 that faces away from the substrate 10. The encapsulation layer 80 covers the first conductive portion 41.

The encapsulation layer 80 primarily functions as an encapsulant, serving to reduce the risk of abnormalities in the light-emitting structures 21 caused by intrusion of water, oxygen, etc., into the light-emitting structures 21. Typically, the encapsulation layer 80 is arranged to cover the first electrode 42 to provide encapsulation protection for the light-emitting structures 21 beneath the first electrode 42. On this basis, in the embodiments of the present application, the encapsulation layer 80 is also configured to cover the first conductive portion 41, enabling the encapsulation layer to also provide encapsulation protection for the first conductive portion 41.

The structure and material composition of the encapsulation layer 80 are not limited in the embodiments of the present application. As an example, the encapsulation layer 80 may be composed of three stacked film layers, and may include two inorganic layers and an organic layer sandwiched between the two inorganic layers.

In some embodiments, the display panel has a first area and a second area arranged around the first area. The encapsulation layer 80 is at least partially located in the second area and covers the first through hole H1.

As can be seen from the foregoing, the first conductive portion 41 can extend to the first through hole H1 and be electrically connected to the first potential portion D1 exposed in the first through hole H1. On this basis, in the embodiments of the present application, the encapsulation layer 80 is configured to cover the first through hole H1 to ensure encapsulation reliability at the connection position between the first potential portion D1 and the first conductive portion 41, thereby improving the reliability of the electrical connection between them.

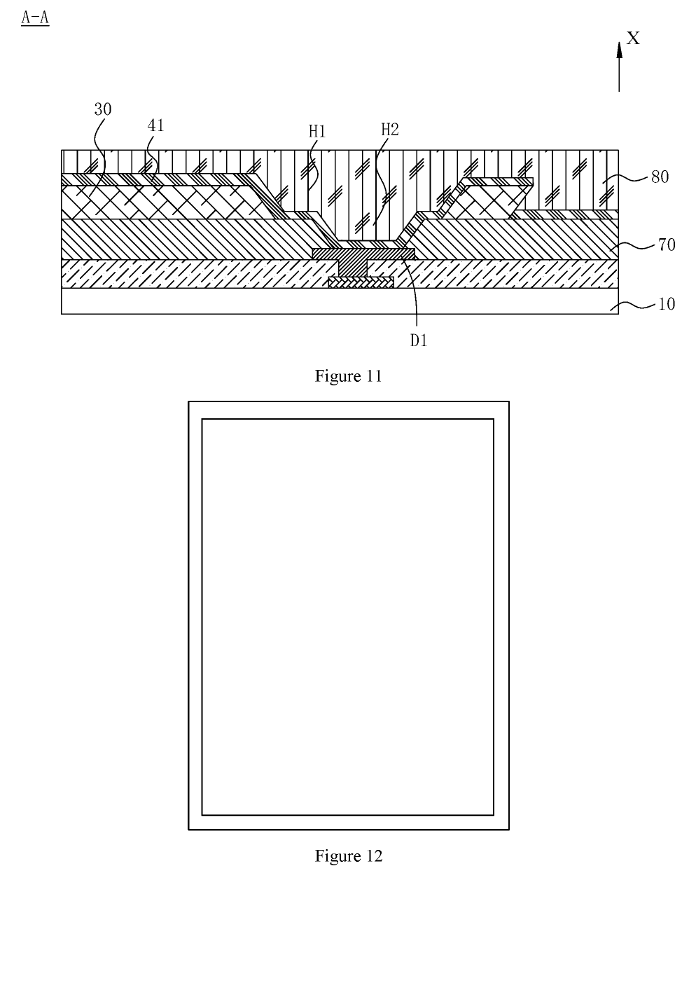

In a second aspect, referring to FIG. 12, the embodiments of the present application provide a display apparatus, including a display panel in any one of the above implementations.

The display apparatus provided in the embodiments of the present application has the beneficial effects of the display panel in any one of the above implementations.

Reference is made to the above description of the beneficial effects of the display panel for details which will not be repeated in the embodiments of the present application.

The above descriptions are merely specific implementations of the present application. It is understood that, for convenience and conciseness of description, for replacement of other connection manners described above, reference may be made to the corresponding processes in the foregoing method embodiments, which will not be described in detail herein. It should be understood that the scope of protection of the present application is not limited thereto, any equivalent modification or replacement that can be easily conceived within the scope disclosed in the present application in the art shall fall within the scope of protection of the present application.

What is claimed is:

1. A display panel, comprising:
a substrate;
a first potential portion arranged on a side of the substrate;
an isolation structure arranged on a side of the first potential portion that faces away from the substrate, the isolation structure being provided with a first through hole extending through the isolation structure in a thickness direction of the substrate, and the first potential portion being at least partially exposed in the first through hole;
a light-emitting functional layer arranged on the side of the first potential portion that faces away from the substrate, the light-emitting functional layer comprising a plurality of light-emitting structures, and adjacent light-emitting structures being isolated from each other by means of the isolation structure; and
a first conductive portion located on a side of the isolation structure that faces away from the substrate, the first conductive portion being at least partially located in the first through hole and being electrically connected to the first potential portion.

2. The display panel according to claim 1, further comprising a first electrode arranged on a side of the light-emitting functional layer that faces away from the substrate, an orthographic projection of the first electrode on the substrate overlapping with an orthographic projection of a light-emitting structure on the substrate;
wherein the first electrode and the first conductive portion are insulated from each other by means of the isolation structure.

3. The display panel according to claim 2, wherein a plurality of first electrodes are provided, and adjacent first electrodes are respectively arranged on different sides of the isolation structure.

4. The display panel according to claim 2, wherein the orthographic projection of the first electrode on the substrate overlaps with orthographic projections of the plurality of light-emitting structures on the substrate.

5. The display panel according to claim 2, wherein the first electrode and the first conductive portion comprise the same material.

6. The display panel according to claim 2, wherein in a direction away from the substrate, a cross-sectional dimension of at least part of the isolation structure exhibits a gradually increasing trend; and
the isolation structure comprises a first part and a second part located on a side of the first part that faces away from the substrate, and an orthographic projection of the first part on the substrate is located within an orthographic projection of the second part on the substrate.

7. The display panel according to claim 2, wherein the first conductive portion is used for transmitting touch signals.

8. The display panel according to claim 7, wherein the display panel has a first area and a second area arranged around the first area, wherein the light-emitting structures are arranged in the first area, and the first potential portion is arranged in the second area.

9. The display panel according to claim 2, further comprising a support portion located on a side of the first potential portion and in contact with the isolation structure, the support portion being at least partially located in the first through hole, in a direction parallel to a plane of the substrate, the support portion having a first surface close to the first potential portion, and in a direction away from the substrate, the first surface has a tendency to approach the isolation structure;
wherein the first conductive portion extends to the first potential portion via the first surface.

10. The display panel according to claim 9, wherein the display panel has a first area and a second area arranged around the first area, wherein the first potential portion is arranged in the second area; and
the support portion is located on a side of the first potential portion that faces the first area.

11. The display panel according to claim 10, wherein the isolation structure has a first sidewall located on a side of the first through hole close to the first area, and the support portion covers at least part of the first sidewall; or
part of the support portion is located on the side of the isolation structure that faces away from the substrate.

12. The display panel according to claim 2, further comprising a pixel definition layer arranged on the side of the first potential portion that faces away from the substrate, the pixel definition layer comprising a pixel defining portion and pixel openings enclosed by the pixel defining portion, wherein the light-emitting structures are at least partially located in the pixel openings, and the isolation structure is arranged on a side of the pixel defining portion that faces away from the substrate; and
the pixel defining portion is provided with a second through hole extending through the pixel defining portion in the thickness direction, the first through hole is in communication with the second through hole, and the first potential portion is at least partially exposed in the second through hole.

13. The display panel according to claim 12, wherein an orthographic projection of the second through hole on the substrate is located within an orthographic projection of the first through hole on the substrate.

14. The display panel according to claim 12, further comprising a second potential portion arranged on a side of the pixel definition layer that faces the substrate, the pixel defining portion being provided with a third through hole extending through the pixel defining portion in the thickness direction, wherein the second potential portion is at least partially exposed in the third through hole; and
the first electrode is at least partially located in the third through hole and is electrically connected to the second potential portion.

15. The display panel according to claim 14, wherein the display panel has a first area and a second area arranged around the first area, the second potential portion being arranged in the second area.

16. The display panel according to claim 14, wherein the first potential portion and the second potential portion are arranged in the same layer.

17. The display panel according to claim 2, further comprising a second electrode arranged on a side of the light-emitting structure that faces the substrate, wherein the first potential portion and the second electrode are arranged in the same layer; and
the first potential portion and the second electrode comprise the same material.

18. The display panel according to claim 2, further comprising an encapsulation layer arranged on a side of the first electrode that faces away from the substrate, the encapsulation layer covering the first conductive portion.

19. The display panel according to claim 18, wherein the display panel has a first area and a second area arranged around the first area, wherein the encapsulation layer is at least partially located in the second area and covers the first through hole.

20. A display apparatus, comprising:
a display panel, comprising:
a substrate;
a first potential portion arranged on a side of the substrate;
an isolation structure arranged on a side of the first potential portion that faces away from the substrate, the isolation structure being provided with a first through hole extending through the isolation structure in a thickness direction of the substrate, and the first potential portion being at least partially exposed in the first through hole;
a light-emitting functional layer arranged on the side of the first potential portion that faces away from the substrate, the light-emitting functional layer comprising a plurality of light-emitting structures, and adjacent light-emitting structures being isolated from each other by means of the isolation structure; and
a first conductive portion located on a side of the isolation structure that faces away from the substrate, the first conductive portion being at least partially located in the first through hole and being electrically connected to the first potential portion.
